(19) United States
(12) Patent Application Publication
(10) Pub. No.: US 2025/0225901 A1
(43) Pub. Date: Jul. 10, 2025

(54) OFFSET CALIBRATION CIRCUIT AND DATA DRIVING DEVICE INCLUDING THE SAME

(71) Applicant: LX SEMICON CO., LTD., Daejeon (KR)

(72) Inventors: Jin Ho KIM, Daejeon (KR); Jong Suk LEE, Daejeon (KR)

(73) Assignee: LX SEMICON CO., LTD., Daejeon (KR)

(21) Appl. No.: 19/012,319

(22) Filed: Jan. 7, 2025

(30) Foreign Application Priority Data
Jan. 8, 2024 (KR) 10-2024-0002749
Oct. 7, 2024 (KR) 10-2024-0135858

(51) Int. Cl. G09G 3/20; H03F 3/04

(52) U.S. Cl. CPC G09G 3/20; H03F 3/04; G09G 2310/0275; G09G 2310/0291; G09G 2320/0693; H03F 2200/375

(57) ABSTRACT

An offset calibration circuit may achieve more precise offset calibration by intentionally applying, as an input to an amplifier in a receiver circuit, a fixed voltage and variable voltages that have constant voltage differences between adjacent voltages with respect to the fixed voltage, and feeding back to a biasing circuit an average value obtained through a biasing process performed by the biasing circuit to calibrate the offset.

### CROSS-REFERENCE TO RELATED APPLICATIONS

This application claims the priorities of Korean Patent Applications No. 10-2024-0002749, filed on Jan. 8, 2024, and No. 10-2024-0135858 filed on Oct. 7, 2024, which are hereby incorporated by reference in their entirety.

### BACKGROUND

### Field of the Disclosure

The present disclosure relates to an offset calibration circuit and a data driving device including the same, and more particularly, to an offset calibration circuit that calibrates offsets by applying voltages having voltage differences to an amplifier and performing biasing, and a data driving device including the same.

### Description of the Background

With the development of the information society, the demand for display devices that display images is increasing in various forms. In response to this demand, various types of display devices, such as a conventional liquid crystal display device (LCD) and an organic light emitting display device (OLED), are being utilized.

Such display devices are equipped with a source driver integrated circuit (IC) for supplying data voltages to data lines of a display panel, a gate driver IC for sequentially supplying gate pulses (or scan pulses) to gate lines (or scan lines) of the display panel, a timing controller for controlling the source driver IC and the gate driver IC, and the like.

The source driver IC receives a signal from an external source, such as a timing controller, through a receiver circuit and transmits the signal to an internal circuit. If the internal circuit receives the signal inputted from the external source as it is, the magnitude of the signal is not sufficient to restore data, so the receiver circuit amplifies the signal through an internal amplifier (receiver amplifier) and then transmits it to the internal circuit. The amplifiers of the receiver circuit that actually operate have their own offset, and the offsets of these amplifiers may distort the signal transmitted to the internal circuit, causing errors in the restored data.

### SUMMARY

Accordingly, the present disclosure is directed to an offset calibration circuit and a data driving device including the same that substantially obviate one or more of problems due to limitations and disadvantages described above.

More specifically, the present disclosure is to provide an offset calibration circuit that calibrates offsets by applying voltages with voltage differences to an amplifier and performing biasing, and a data driving device including the same.

The present disclosure is also to provide an offset calibration circuit that calibrates offsets by applying a fixed voltage and variable voltages, instead of an external signal, to an amplifier and performing biasing, and a data driving device including the same.

Further, the present disclosure is to provide an offset calibration circuit that calibrates offsets based on an average value obtained through biasing for a plurality of variable voltages, and a data driving device including the same.

The present disclosure is not limited to those mentioned above, and other features not explicitly stated will be clearly understood by those skilled in the art from the following description.

To achieve these and other advantages and in accordance with the present disclosure, as embodied and broadly described, an offset calibration circuit includes: a reference signal generation circuit configured to generate a fixed voltage and a plurality of variable voltages having a plurality of voltage differences from the fixed voltage; a biasing circuit connected to a plurality of amplifiers and configured to sequentially increase a current flowing through a connected node; and a plurality of registers in which binary code values of the biasing circuit are stored, wherein the plurality of amplifiers include a first amplifier configured to differentially receive an external signal and differentially output the signal to a next amplifier, and a second amplifier configured to differentially receive a differential output signal of one of the plurality of amplifiers and output the signal to an internal circuit, wherein the external signal differentially inputted to the first amplifier is blocked, the fixed voltage and one of the plurality of variable voltages are inputted to the first amplifier, the biasing circuit is alternately connected to differential input nodes of the second amplifier to sequentially increase a current flowing therethrough, a first binary code value of the biasing circuit, which causes an output of the second amplifier to transition from a low level to a high level, is stored in one of the plurality of registers, and offsets of the plurality of amplifiers are calibrated based on an average value of a plurality of the first binary code values stored in the plurality of registers for the respective plurality of variable voltages.

In another aspect of the present disclosure, a data driving device includes: a receiver circuit configured to receive an external signal and transmit it to an internal circuit, and include a plurality of amplifiers; and an offset calibration circuit configured to calibrate offsets of the plurality of amplifiers of the receiver circuit, wherein the plurality of amplifiers includes: a first amplifier configured to differentially receive the external signal and differentially output the signal to a next amplifier; and a second amplifier configured to differentially receive a differential output signal of one of the plurality of amplifiers and output the signal to the internal circuit, and the offset calibration circuit includes a reference signal generation circuit, a biasing circuit, and a plurality of registers, wherein the reference signal generation circuit generates a fixed voltage and a plurality of variable voltages having a plurality of voltage differences from the fixed voltage, the external signal differentially inputted to the first amplifier is blocked, the fixed voltage and one of the plurality of variable voltages are inputted to the first amplifier, the biasing circuit is alternately connected to differential input nodes of the second amplifier to sequentially increase a current flowing therethrough, a first binary code value of the biasing circuit, which causes an output of the second amplifier to transition from a low level to a high level, is stored in one of the plurality of registers, and the offsets of the plurality of amplifiers are calibrated based on an average value of a plurality of the first binary code values stored in the plurality of registers for the respective plurality of variable voltages.

Specific matters of other aspects are included in the detailed description and the drawings.

According to various aspects of the present disclosure, the offset calibration circuit may achieve more precise offset calibration by intentionally applying, as the input to an amplifier in the receiver circuit, a fixed voltage and variable voltages that have constant voltage differences between adjacent voltages with respect to the fixed voltage, and feeding back to the biasing circuit an average value obtained through the biasing process performed by the biasing circuit to calibrate the offset.

According to aspects of the present disclosure, the offset calibration circuit is an additional circuit that does not alter the circuit structure related to the amplifier of the receiver circuit. Therefore, the receiver circuit of a source driver circuit with the offset calibration circuit applied may achieve enhanced stability in terms of circuit modification in addition to the effect of offset calibration.

According to aspects of the present disclosure, the offset calibration circuit may secure a wider adjustable offset range by performing two offset calibration stages using two biasing circuits for the receiver circuit including three or more amplifiers.

The effects of the present disclosure are not limited to the aforementioned effects, and other effects not explicitly mentioned will be clearly understood by those skilled in the art from the following description.

### BRIEF DESCRIPTION OF THE DRAWINGS

The above and other features and advantages of the present disclosure will become more apparent to those of ordinary skill in the art by describing exemplary aspects thereof in detail with reference to the attached drawings, in which:

FIG. 1 is a block diagram of a display device according to one aspect of the present disclosure;

FIG. 2 is a circuit diagram illustrating a receiver circuit of a source driver circuit of the present disclosure;

FIG. 3 is a circuit diagram of a source driver circuit according to one aspect of the present disclosure;

FIG. 4 is a circuit diagram of a switching circuit included in an offset calibration circuit according to one aspect of the present disclosure;

FIG. 5 is a circuit diagram of a reference signal generation circuit included in an offset calibration circuit according to one aspect of the present disclosure;

FIG. 6 is a circuit diagram of a biasing circuit included in an offset calibration circuit according to one aspect of the present disclosure;

FIG. 7 is a flowchart illustrating an offset calibration method according to one aspect of the present disclosure;

FIGS. 8 and 9 are tables illustrating offset calibration results according to one aspect of the present disclosure;

FIG. 10 is a circuit diagram of a source driver circuit according to another aspect of the present disclosure;

FIG. 11 is a circuit diagram of a source driver circuit according to still another aspect of the present disclosure; and

FIG. 12 is a timing diagram of an offset calibration enable signal according to another aspect of the present disclosure.

### DETAILED DESCRIPTION

The advantages and features of the present disclosure, and methods of achieving them will be apparent from the aspects described in detail below in conjunction with the accompanying drawings. However, the present disclosure is not limited to the following aspects, but may be implemented in various different forms; rather, the present aspects are provided to make the description of the present disclosure complete and to allow those skilled in the art to fully understand the scope of the present disclosure, and the present disclosure is defined only within the scope of the appended claims.

The shapes, sizes, proportions, angles, numbers and the like shown in the accompanying drawings for the purpose of illustrating the aspects of the present disclosure are merely examples, and the present disclosure is not limited thereto. Identical reference numerals may designate identical components throughout the description. Further, in describing the present disclosure, detailed descriptions of known related technologies may be omitted if it is considered to unnecessarily obscure the gist of the present disclosure. The terms such as “including,” “having,” and “consisting of” used herein are generally intended to allow other components to be added unless the terms are used with the term “only.” References to components of a singular noun include the plural of that noun, unless specifically stated otherwise.

In interpreting components, they are construed to include a margin of error, even if it is not explicitly stated.

When describing a positional relationship, for example, “on,” “above,” “below,” or “next to” describes the positional relationship of two parts, one or more other parts may be located between the two parts, unless “immediately” or “directly” is used.

When describing a temporal contextual relationship is described, for example, such as “after,” “following,” “next to,” or “before,” it may also include non-contiguous cases unless “immediately” or “directly” is used.

As used herein, the term “part” may refer to a unit that processes at least one function or operation, such as a software or hardware component. The functions provided by the “part” may be performed separately by multiple components, or it may be integrated with other additional components. In this specification, the “part” may be implemented in a single circuit or in a plurality of circuits, or in a single device or in a plurality of devices.

Each of the features of various aspects described herein may be coupled or combined with one another in whole or in part, and may be technologically interlocked and operated in various ways, and each of the aspects may be carried out independently or in conjunction with one another.

Switch elements used in a source driver circuit of the present specification may be implemented as transistors of n-type or p-type metal oxide semiconductor field effect transistor (MOSFET) structure. The technical scope of the present specification is not limited by the types of transistors exemplified in the following aspects. The transistor is a three-electrode element including a gate, a source, and a drain. The source is an electrode that supplies carriers to the transistor. Within the transistor, carriers begin to flow from the source. The drain is an electrode through which carriers exit the transistor. In other words, the flow of carriers in a MOSFET occurs from the source to the drain. In the case of an n-type MOSFET (NMOS), the carrier is an electron, and thus the source voltage is lower than the drain voltage to allow electrons to flow from the source to the drain. In an n-type MOSFET, since electrons flow from the source to the drain, the direction of current is from the drain to the source. In the case of a p-type MOSFET (PMOS), the carrier is a hole, and thus the source voltage is higher than the drain voltage to allow holes to flow from the source to the drain. In a p-type MOSFET, since holes flow from the source to the drain, current flows from the source to the drain. It should be noted that the source and drain of a MOSFET are not fixed. For example, the source and drain of a MOSFET may be switched depending on the applied voltage. In the present specification, the source and drain of a transistor may be referred to as the first and second electrodes, and the technical scope of the present specification is not limited by the source and drain electrodes of the transistor.

Hereinafter, an offset calibration circuit and a data driving device including the same according to aspects of the present specification will be described with reference to the accompanying drawings.

A display device according to one aspect of the present disclosure includes a display panel in which a plurality of data lines and a plurality of gate lines are formed, a plurality of source driver circuits for driving the plurality of data lines, a gate driver circuit for sequentially driving the plurality of gate lines, and a timing controller for controlling the source driver circuits and the gate driver circuit.

The timing controller provides digital image data to the source driver circuit, and controls the source driver circuit and the gate driver circuit such that a source driving signal corresponding to the digital image data is accurately supplied to the display panel.

The timing controller may include lock fail data into an input signal at preset intervals and transmit it to the source driver circuit. Here, the preset interval may be set as a portion of a vertical blank interval between frames. In one aspect, the timing controller may be configured to include the lock fail data in the input signal and transmit it periodically for every frame.

The timing controller may include the digital image data and control data into the input signal along with a clock signal and transmit them to the source driver circuit through a data transmission line during a display interval, and may include the lock fail data into the input signal and transmit it to the source driver circuit during a portion of the vertical blank interval.

During the display interval, the source driver circuit restores the clock signal, digital image data, and control data from the input signal provided by the timing controller, aligns the restored digital image data, converts the aligned digital image data into an analog source driving signal, and supplies the source driving signal to the data lines of the display panel. A single source driver circuit may be configured as a single integrated circuit (SD-IC), and the number of source driver circuits may be determined in consideration of the size and resolution of the display panel.

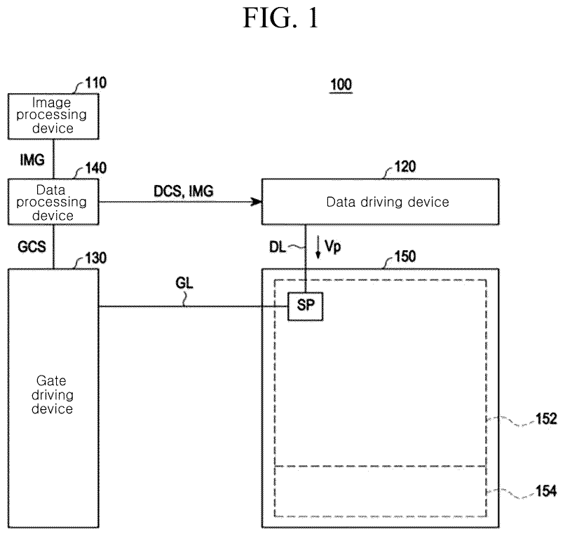

FIG. 1 is a block diagram of a display device according to one aspect of the present disclosure. Referring to FIG. 1, a display device 100 may include a plurality of panel driving devices (or panel driving circuits) 110, 120, 130, and 140, and a display panel 150.

The display panel 150 may include a plurality of data lines DL, a plurality of gate lines GL, and a plurality of pixels arranged therein. The pixel P may be composed of a plurality of sub-pixels SP.

Here, the sub-pixels may include red (R) sub-pixel, green (G) sub-pixel, blue (B) sub-pixel, white (W) sub-pixel, and the like. A single pixel may be composed of RGB sub-pixels SP, RGBG sub-pixels SP, RGBW sub-pixels SP, or the like. Hereinafter, for simplicity of description, a single pixel will be described as being composed of RGB sub-pixels.

The panel driving devices (or panel driving circuits) 110, 120, 130, and 140 are devices that generate signals for displaying an image on the display panel 150, and may include at least one of an image processing device (or image processing circuit) 110, a data driving device (or data driving circuit) 120, a gate driving device (or gate driving circuit) 130, or a data processing device (or data processing circuit) 140.

The gate driving device (or gate driving circuit) 130 may supply a gate driving signal of a turn-on voltage or a turn-off voltage to the gate line GL. When the gate driving signal of a turn-on voltage is supplied to the sub-pixel SP, the sub-pixel SP may be connected to the data line DL. Conversely, when the gate driving signal of a turn-off voltage is supplied to the sub-pixel SP, the connection between the sub-pixel SP and the data line DL may be released. The gate driving device 130 may be referred to as a gate driver.

The data driving device (or data driving circuit) 120 may supply a data voltage Vp to the sub-pixel SP through the data line DL. The data voltage Vp supplied to the data line DL may be provided to the sub-pixel SP in response to a gate driving signal. The data driving device 120 may be referred to as a source driver.

The data driving device 120 may include at least one integrated circuit, which may be connected to a bonding pad of the panel 150 in a tape automated bonding (TAB) type or a chip on glass (COG) type, or may be formed directly on the panel 150. Depending on the aspect, it may be formed by being integrated into the panel 150.

Additionally, the data driving device 120 may be implemented as a chip on film (COF) type. When the data driving device 120 is formed as a chip on glass type, the integrated circuits constituting the data driving device 120 may be formed on a peripheral portion 154 of an active area 152 where the sub-pixels SP are disposed. To maximize the active area 152 of the panel 150, the area of the peripheral portion 154 may be reduced, and the chip size of the integrated circuits constituting the data driving device 120 may also be reduced.

The data processing device (or data processing circuit) 140 may supply a control signal to the gate driving device 130 and the data driving device 120. For example, the data processing device 140 may transmit a gate control signal GCS to the gate driving device 130 to initiate scanning. Additionally, the data processing device 140 may output image data IMG to the data driving device 120. Furthermore, the data processing device 140 may transmit a data control signal DCS to the data driving device 120 to control the supply of the data voltage Vp to each sub-pixel SP. The data processing device 140 may be referred to as a timing controller.

The image processing device 110 may generate the image data IMG and transmit it to the data processing device 140. The image processing device 110 may be referred to as a host.

The data processing device 140 may include at least one data processing circuit implemented in the form of an integrated circuit, and may include at least one data driving circuit implemented in the form of an integrated circuit. A high-speed communication interface may be formed between the data processing circuit and the data driving circuit, and the data processing circuit may transmit the data control signal DCS and/or the image data IMG to the data driving circuit through the high-speed communication interface. In the aspects described below, from the perspective of devices that transmit and receive the image data IMG, the device that transmits the image data will be referred to as a display processing device, and the device that receives the image data will be referred to as a display driving device.

For example, referring to FIG. 1, as the image data IMG is transmitted from the image processing device 110 to the data processing device 140, the image processing device 110 may be referred to as the display processing device and the data processing device 140 may be referred to as the display driving device.

Additionally, as the image data IMG is transmitted from the data processing device 140 to the data driving device 120, the data processing device 140 may be referred to as the display processing device, and the data driving device 120 may be referred to as the display driving device.

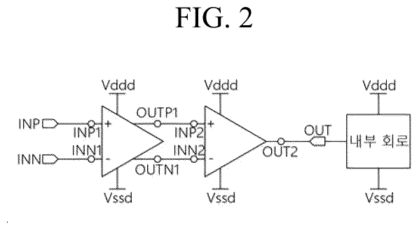

FIG. 2 is a circuit diagram illustrating a receiver circuit of a source driver circuit according to an aspect of the present disclosure.

An amplifier of the receiver circuit in the source driver circuit may, for example, receive a differential input signal with a low swing width through differential input terminals (or differential input nodes) INP and INN from an external device or circuit, such as a timing controller, and amplify the signal's magnitude to transmit it to an internal circuit included in the source driver circuit.

If the internal circuit directly receives an external signal, the magnitude of the signal is insufficient to restore the data, and thus the receiver circuit may amplify the signal using an internal amplifier (receiver amplifier) and transmit it to the internal circuit. The amplifiers of the receiver circuit in actual operation have their own offsets, and such offsets in the amplifiers may distort a signal transmitted to the internal circuit, causing an error in restored data. For example, if the offset of the amplifier exceeds the magnitude (i.e., the swing width) of an input signal, an error may occur in data restored after being transmitted to the internal circuit through the amplifier.

Offsets may occur, for example, due to mismatches arising from when the layout of a semiconductor is not drawn symmetrically in a semiconductor process step. Even if the circuits are identical, offsets may still occur in such cases. In the case of process-induced offsets, each semiconductor chip may have a different offset value, and thus there is a problem that a uniform value cannot be applied for calibration across all chips.

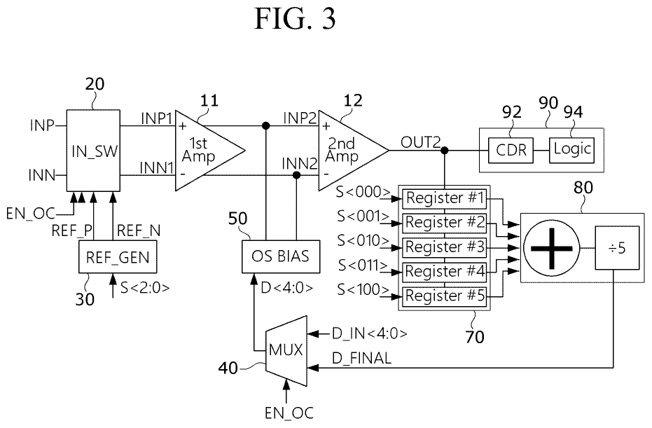

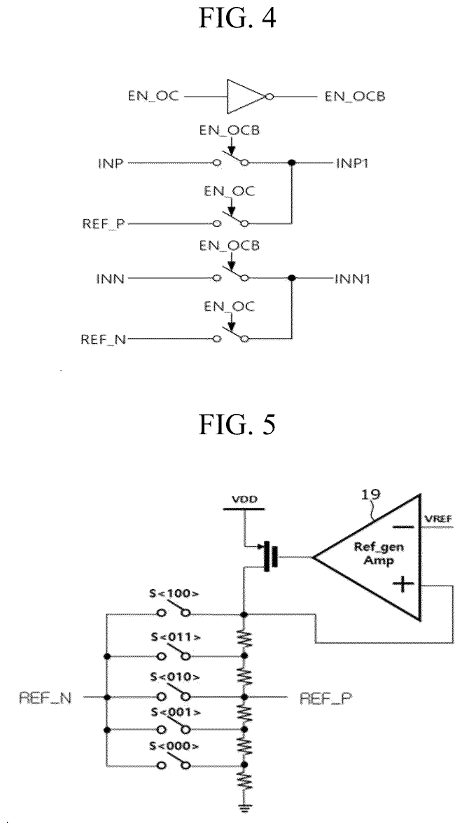

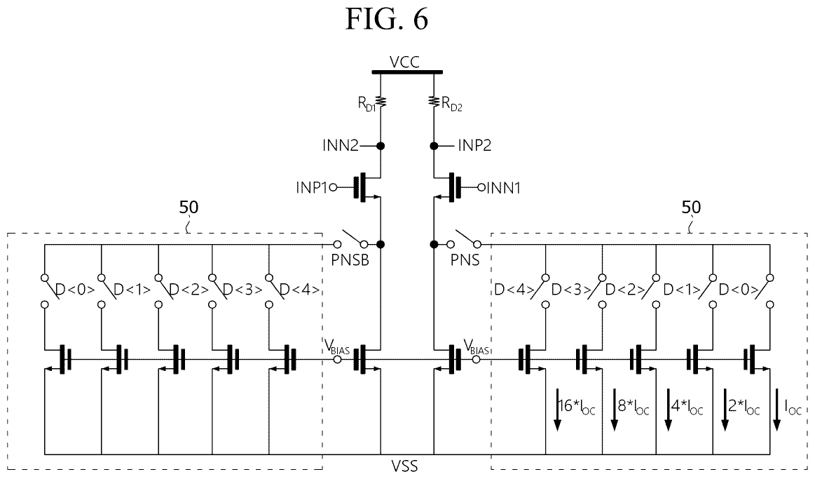

FIG. 3 is a circuit diagram of a source driver circuit according to one aspect of the present disclosure, FIG. 4 is a circuit diagram of a switching circuit included in an offset calibration circuit according to one aspect of the present disclosure, FIG. 5 is a circuit diagram of a reference signal generation circuit included in an offset calibration circuit according to one aspect of the present disclosure, and FIG. 6 is a circuit diagram of a biasing circuit included in an offset calibration circuit according to one aspect of the present disclosure.

The source driver circuit according to one aspect of the present disclosure may include the receiver circuit, an internal circuit 90, and the offset calibration circuit.

The receiver circuit may include a first amplifier 11 and a second amplifier 12. The receiver circuit may receive an external signal through differential input terminals INP1 and INN1 of the first amplifier 11 and output it differentially to the second amplifier 12, and the second amplifier 12 may receive the differential output signal of the first amplifier 11 and output an output signal to transmit an amplified signal to the internal circuit 90. Here, the output signal of the second amplifier 12 is an analog signal created by refining the noise of the input data and the magnitude of the signal to be suitable for the protocol. A signal received from an external transmitter may have a small magnitude or include noise. To ensure smooth restoration of the received signal, the signal needs to be amplified to the level required by the internal circuit 90, which may require two or more amplifiers.

Here, it should be noted that the terms “first amplifier” and “second amplifier” are only named in the arrangement order of the amplifiers in the circuit diagram as shown in FIG. 3, and the technical scope of the present disclosure is not limited by terms such as “first” or “second”. For example, in one aspect of the present disclosure, in a plurality of amplifiers connected in a cascade manner, which receives a differential input and differentially outputs to the differential input terminals of a next amplifier, the amplifier positioned at the very beginning may be referred to as a “first amplifier,” while the amplifier positioned at the very end may be referred to as a “second amplifier.” What these terms refer to should be interpreted with a specific description.

The internal circuit 90 may include a restoration circuit 92 and a logic circuit 94, and may also be circuits provided inside the source driver circuit including these circuits. In one aspect, the restoration circuit 92 may be a clock and data recovery (CDR) circuit, but is not limited thereto. When the restoration circuit 92 is configured as a CDR circuit, it may receive serial data with a reference clock signal embedded therein from the external device or circuit, and may separate the data from the reference clock signal to extract the reference clock signal. Subsequently, the extracted reference clock signal may be used to sample the received data, thereby accurately reconstructing the data. The logic circuit 94 may process the digital image data restored by the restoration circuit 92.

The offset calibration circuit according to one aspect of the present disclosure may include a switching circuit (IN_SW) 20, a reference signal generation circuit (REF_GEN) 30, a multiplexer (MUX) circuit 40, a biasing circuit (OS BIAS) 50, a plurality of registers 70, and an arithmetic circuit 80.

The switching circuit 20 may supply, to the differential input terminals (or differential input nodes) INP1 and INN1 of the first amplifier 11 of the receiver circuit to which an external signal is applied, signals generated by the reference signal generation circuit 30, instead of the external signal. Referring to FIG. 4, the offset calibration circuit may control the switching circuit 20 by using an offset calibration enable signal EN_OC and an inverted signal EN_OCB of the offset calibration enable signal.

When the offset calibration circuit begins operation, the offset calibration enable signal EN_OC may transition to an on level, and accordingly, the inverted signal EN_OCB of the offset calibration enable signal may transition to an off level. A switch element controlled by the inverted signal EN_OCB of the offset calibration enable signal may be turned off, disconnecting the differential input terminals INP1 and INN1 of the first amplifier 11 from the terminals INP and INN to which the external signal is inputted. Additionally, a switch element controlled by the offset calibration enable signal EN_OC may be turned on, connecting the differential input terminals INP1 and INN1 of the first amplifier 11 to REF_P and REF_N nodes to which signals generated by the reference signal generation circuit 30 are supplied.

Therefore, when offset calibration according to one aspect of the present disclosure begins to be performed, the external signal inputted to the first amplifier 11 may be blocked by the operation of the switching circuit 20, and signals generated by the reference signal generation circuit 30 of the offset calibration circuit may be supplied instead.

The reference signal generation circuit 30 may be a circuit as shown in FIG. 5 in one aspect of the present disclosure, and may generate a fixed voltage and variable voltages having a plurality of voltage differences from the fixed voltage. For example, the reference signal generation circuit 30 may output a fixed voltage Vs to the REF_P node, and may generate variable voltages including a voltage equal to the fixed voltage Vs and voltages having constant voltage differences from the fixed voltage, e.g., Vs+20 mV and Vs+40 mV in the increasing direction and Vs−20 mV and Vs−40 mV in the decreasing direction, and output the variable voltages to the REF_N node. The variable voltages generated in this manner may include the voltage value of the fixed voltage, and all voltage differences between adjacent voltage values may be the same as 20 mV. The voltage differences between adjacent voltage values may be set to the same value suitable for offset calibration and is not limited to a specific value.

In one aspect, the reference signal generation circuit 30 may include a p-type transistor, a reference signal generation amplifier (Ref_gen Amp) 19, a plurality of resistors connected in series, and a plurality of switches. A power voltage VDD may be applied to the second electrode of the transistor, the gate electrode of the transistor may be connected to the output of the reference signal generation amplifier (Ref_gen Amp) 19, and the first electrode of the transistor may be connected to the positive (+) terminal of the reference signal generation amplifier 19. A reference voltage VREF may be supplied to the negative (−) terminal of the reference signal generation amplifier 19.

In one aspect, five resistors may be connected in series to the first electrode of the transistor, and the final resistor may be connected to ground GND. Switch elements, whose on-off states are controlled by a binary code value, may be connected to respective nodes between the resistors to allow the variable voltages to be outputted to the REF_N node in correspondence with the fixed voltage outputted to the REF_P node. The binary code value for controlling the switch elements may be 3 bits, such as S<2:0>. When the switch element is turned on by an S<000> control signal, the smallest variable voltage may be outputted, and when the switch element is turned on by an S<100> control signal, the largest variable voltage may be outputted.

In one aspect shown in FIG. 5, the reference signal generation circuit 30 is described as being configured to generate five variable voltages, but the technical scope of the present disclosure is not limited thereto. The number of variable voltages that may be generated may be seven, nine, or more, and it may be adjusted according to a user setting.

Additionally, in one aspect of the present disclosure, the fixed voltage outputted from the reference signal generation circuit 30 may be inputted to a INP1 node of the differential input terminals of the first amplifier 11, and the variable voltage may be inputted to the INN1 node of the differential input terminals of the first amplifier 11, but is not limited thereto. The offset calibration may also be performed in such a way that the fixed voltage is applied to the INN1 node and the variable voltage is applied to the INP1 node.

The biasing circuit 50 is alternately connected to differential input terminals of the second amplifier 12 and sequentially increases a current flowing through the connected (or electrically connected) differential input terminals. Referring to FIG. 6, the biasing circuit 50 according to one aspect of the present disclosure may be electrically connected to the differential input nodes INP2 and INN2 of the second amplifier 12 by the on-off operations of two switch elements PNS and PNSB. The switch elements PNS and PNSB may operate exclusively, allowing the biasing circuit 50 to be alternately connected to the differential input terminals of the second amplifier 12.

The biasing circuit 50 may be a circuit corresponding to the dashed box in FIG. 6 in one aspect of the present disclosure, and may sequentially increase the current flowing through the nodes connected to the second amplifier 12 through the switch elements controlled by a binary code value.

In one aspect, the biasing circuit 50 may include a plurality of transistors and a plurality of switch elements. The plurality of transistors may be connected in parallel such that their gate electrodes are connected at a single node to a gate electrode of a transistor to which a bias voltage V_{BIAS} of the amplifier is applied. The first electrodes of the plurality of transistors may be connected to a single node through switch elements (D<0>, D<1>, and the like) whose on-off states are controlled by a binary code value, and the node to which the first electrodes of the transistors are connected may be electrically connected to the differential input terminal of the second amplifier 12 through the switch element PNS or PNSB.

In one aspect, the operation performed by the biasing circuit 50 to increase the current flowing to the differential input nodes electrically connected to the biasing circuit 50 may be as follows. Among the switch elements connected to the plurality of transistors, when the switch element controlled by D<0> is turned on, a preset current of loc may additionally flow. When the switch element controlled by D<1> is turned on, a current (2×Ioc) twice the preset current Ioc may additionally flow. Similarly, when the switch elements controlled by D<2>, D<3>, and D<4> are turned on, currents four times (4×Ioc), eight times (8×Ioc), and sixteen times (16×Ioc) the preset current Ioc may additionally flow, respectively.

In one aspect as shown in FIG. 6, a configuration in which the biasing circuit 50 includes five transistors and five switch elements and sequentially increases the current using a 5-bit binary code value such as D<4:0> has been described, but the technical scope of the present disclosure is not limited thereto. If precise offset calibration is required through finer control of current, the number of transistors and switch elements may further increase, and the number of such transistors and switch elements may be adjusted according to the user setting.

The MUX circuit 40 may be controlled by the offset calibration enable signal EN_OC and may output a binary code value D_IN<4:0> or an offset calibration-related feedback value D_FINAL used in the biasing circuit 50 to the biasing circuit 50. When the offset calibration begins and the offset calibration enable signal EN_OC is at an on level, the MUX circuit 40 may output the binary code value D_IN<4:0> and transmit it to the biasing circuit 50, and when the offset calibration enable signal EN_OC is at an off level in an interval where offset calibration is not performed, the MUX circuit 40 may output the feedback value D_FINAL to the biasing circuit 50, thereby allowing the offset of the amplifier in the receiver circuit to be calibrated.

In a state before the offset is calibrated, the MUX circuit 40 may output the feedback value D_FINAL to the biasing circuit 50 even before the offset calibration begins, and in one aspect, the initial setting value of the feedback value D_FINAL may be set to PNSB-ON, PNS=OFF, and D<00000>. After the offset calibration is performed, the feedback value D_FINAL is changed to a value reflecting the offset calibration, and through the feedback value D_FINAL, the binary code value that determines the operation of the switch elements of the biasing circuit 50 may be determined to calibrate the offset of the amplifier of the receiver circuit.

The plurality of registers 70 may store the binary code value of the biasing circuit 50 at a time point when a variation occurs in the output level of the second amplifier 12 outputted after the biasing circuit 50 is connected and operated. In one aspect, the output level of the second amplifier 12 may transition from a low level to a high level as the binary code value of the biasing circuit 50 sequentially increases (i.e., as the current flowing through the differential input nodes of the second amplifier 12 by the biasing circuit 50 sequentially increases). For example, when the output level of the second amplifier 12 transitions from low to high at D<01110>, the binary code value 01110 may be stored in one of the plurality of registers 70.

Each of the plurality of registers 70 may store the binary code values of the biasing circuit 50 to respectively correspond to the variable voltages, having a plurality of voltage differences from the fixed voltage, generated by the reference signal generation circuit 30. Referring again to FIG. 3, exemplarily, a first register Register #1 among the plurality of registers 70 may store a binary code value D<4:0> of the biasing circuit 50 as a result of performing offset calibration based on the fixed voltage Vs and the variable voltage Vs−40 mV generated by the reference signal generation circuit 30. In this case, the binary code value of the reference signal generation circuit 30 that outputs the variable voltage Vs−40 mV is S<000>, and the signal having the binary code value S<000> may also be used as the control signal for determining the register, so that the binary code value D<4:0> of the biasing circuit 50 may be stored in the first register Register #1 as shown in FIG. 3.

In one aspect as shown in FIG. 3, a configuration in which five registers 70 are provided corresponding to a configuration in which the reference signal generation circuit 30 generates five variable voltages has been described, but the technical scope of the present disclosure is not limited thereto. Just as the number of variable voltages that may be generated may be adjusted according to the user setting, the number of registers 70 available for use may also be adjusted according to the user setting.

The arithmetic circuit 80 may calculate an average value based on the binary code values D<4:0> of the biasing circuit 50 respectively stored in the plurality of registers. Additionally, the arithmetic circuit 80 may output the calculated average value and provide it as the feedback value D_FINAL to an input of the MUX circuit 40. As described above, in a state before the offset is calibrated, the feedback value D_FINAL outputted by the arithmetic circuit 80 before the offset calibration begins may be an initial setting value, and in one aspect, the initial setting value of the feedback value D_FINAL may be set to PNSB=ON, PNS=OFF, and D<00000>. After the offset calibration is performed, the feedback value D_FINAL is changed to a value reflecting the offset calibration.

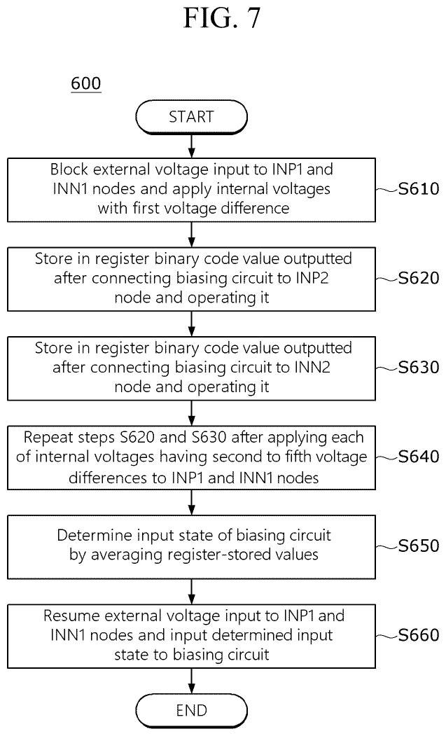

FIG. 7 is a flowchart illustrating an offset calibration method according to one aspect of the present disclosure.

An offset calibration method 600 according to one aspect of the present disclosure may be as follows.

In step S610, an external voltage (or external signal) supplied to the differential input terminals INP1 and INN1 of the first amplifier 11 may be blocked. The external voltage applied from outside may be supplied to the INP and INN nodes, and the connection path between the INP and INN nodes and the differential input terminals of the first amplifier 11 may be blocked by the switching circuit 20 of the offset calibration circuit. Referring again to FIGS. 3 and 4, at the same time, the switching circuit 20 may connect the reference signal output nodes REF_P and REF_N of the reference signal generation circuit 30 to the differential input terminals of the first amplifier 11, thereby applying internal voltages of the source driver circuit having a first voltage difference to the nodes INP1 and INN1. For example, when the fixed voltage is Vs and the variable voltage is Vs−40 mV, the first voltage difference is 40 mV.

In step S620, after connecting the biasing circuit 50 to the INP2 node, which is one of the differential input terminals of the second amplifier 12, the biasing circuit 50 may be operated to sequentially increase the binary code values for controlling the internal switch elements. This may be a biasing determination process for the INN2 node. In this case, referring to FIG. 6, the switch element PNS is in a turn-on state and the switch element PNSB is in a turn-off state. The binary code value D<4:0> of the biasing circuit 50 at the time point when a variation occurs in the output level of the second amplifier 12 (e.g., when the output level transitions to a high level after maintaining a low level) may be stored in one of the plurality of registers 70. For example, when the fixed voltage is Vs and the variable voltage is Vs−40 mV, the binary code value of the reference signal generation circuit 30 that outputs the variable voltage Vs−40 mV is S<000>, and the signal having the binary code value S<000> may also be used as the control signal for determining the register, so that the binary code value D<4:0> of the biasing circuit 50 may be stored in the first register Register #1 as shown in FIG. 3.

In step S630, after connecting the biasing circuit 50 to the INN2 node, which is one of the differential input terminals of the second amplifier 12, the biasing circuit 50 may be operated to sequentially increase the binary code values for controlling the internal switch elements. This may be a biasing determination process for the INP2 node. In this case, referring to FIG. 6, the switch element PNS is in a turn-off state and the switch element PNSB is in a turn-on state. The binary code value D<4:0> of the biasing circuit 50 at the time point when a variation occurs in the output level of the second amplifier 12 (e.g., when the output level transitions to a high level after maintaining a low level) may be stored in one of the plurality of registers 70. For example, when the fixed voltage is Vs and the variable voltage is Vs−40 mV, the binary code value of the reference signal generation circuit 30 that outputs the variable voltage Vs−40 mV is S<000>, and the signal having the binary code value S<000> may also be used as the control signal for determining the register, so that the binary code value D<4:0> of the biasing circuit 50 may be stored in the first register Register #1 as shown in FIG. 3.

The binary code values of the biasing circuit 50 in steps S620 and S630 may all be stored in the first register Register #1. Since the same register is used, a separate data bit may be used in one aspect to distinguish between the binary code value for step S620, which corresponds to the biasing for the INP2 node, and the binary code value for step S630, which corresponds to the biasing for the INN2 node. Alternatively, in one aspect, when one bit as the most significant bit (MSB) is added to the binary code value D<4:0> stored in the first register Register #1 and the binary code value for the INP2 node is stored in the register, a binary code value D<5:0> with an MSB value of 0 may be stored, and when the binary code value for the INN2 node is stored in the register, a binary code value D<5:0> with an MSB value of 1 may be stored. For example, if a variation in the output level of the second amplifier 12 occurs at D<01101>, the register storage value for the INP2 node may be 001101 and the register storage value for the INN2 node may be 101101.

In step S640, the internal voltages of the source driver circuit having a second voltage difference may be applied to the INP1 and INN1 nodes. For example, when the fixed voltage is Vs and the variable voltage is Vs−20 mV, the second voltage difference is 20 mV. In this manner, after changing the variable voltage applied to the differential input terminal of the first amplifier 11, steps S620 and S630 are repeated. The binary code value of the reference signal generation circuit 30 that outputs the variable voltage Vs−20 mV is S<001>, and the signal having the binary code value S<001> may also be used as the control signal for determining the register, so that the binary code value D<4:0> of the biasing circuit 50 may be stored in a second register Register #2 as shown in FIG. 3.

The internal voltages of the source driver circuit with a third voltage difference may now be applied to the INP1 and INN1 nodes. For example, when the fixed voltage is Vs and the variable voltage is Vs, the third voltage difference is 0 V. In this manner, after changing the variable voltage applied to the differential input terminal of the first amplifier 11, steps S620 and S630 are repeated. The binary code value of the reference signal generation circuit 30 that outputs the variable voltage Vs is S<010>, and the signal having the binary code value S<010> may also be used as the control signal for determining the register, so that the binary code value D<4:0> of the biasing circuit 50 may be stored in a third register Register #3 as shown in FIG. 3.

In a similar manner, the internal voltages of the source driver circuit with a fourth voltage difference and a fifth voltage difference may be applied to the INP1 and INN1 nodes. For example, when the fixed voltage is Vs and the variable voltage is Vs+20 mV, the fourth voltage difference is−20 mV, and when the variable voltage is Vs+40 mV, the fifth voltage difference is −40 mV. The subsequent process is the same as that for the first to third voltage differences, and thus, a detailed description thereof will be omitted.

Hereinafter, the register storage operation of one aspect will be exemplarily described.

In a state where the fixed voltage and variable voltage having the first voltage difference are applied to the differential input terminals of the first amplifier 11, the biasing circuit 50 electrically connected to the INP2 node, which is one of the differential input terminals of the second amplifier 12, operates to sequentially increase the binary code value. In this case, if there is no change in the output level of the second amplifier 12, a binary code value D<011111>, with one bit added as the MSB, may be stored in the first register Register #1. Next, the biasing circuit 50 electrically connected to the INN2 node operates to sequentially increase the binary code value and if the output level of the second amplifier 12 transitions from low to high at D<01111>, a binary code value D<101111>, with one bit added as the MSB, may be stored in the first register Register #1. This value may be stored in a manner that replaces the previously stored binary code value D<011111> which represents no change in the output level for the INP2 node.

In a state where the fixed voltage and variable voltage having the second voltage difference are applied to the differential input terminals of the first amplifier 11, the biasing circuit 50 electrically connected to the INP2 node, which is one of the differential input terminals of the second amplifier 12, operates to sequentially increase the binary code value. In this case, if there is no change in the output level of the second amplifier 12, a binary code value D<011111>, with one bit added as the MSB, may be stored in the second register Register #2. Next, the biasing circuit 50 electrically connected to the INN2 node operates to sequentially increase the binary code value and if the output level of the second amplifier 12 transitions from low to high at D<01110>, a binary code value D<101110>, with one bit added as the MSB, may be stored in the second register Register #2. This value may be stored in a manner that replaces the previously stored binary code value D<011111> which represents no change in the output level for the INP2 node.

The register storage operation may also be performed in a similar manner for the fixed and variable voltages having the third to fifth voltage differences. As a result of the biasing in connection with the INP2 node, no change occurs in the output level of the second amplifier 12, and thus the binary code value D<011111>, with one bit added as the MSB, may be stored in each of the third to fifth registers Register #3 to #5. As a result of the biasing in connection with the INN2 node, the binary code values D<01101>, D<01100>, and D<01011>, which represent a change in the output level of the second amplifier 12, may be stored as binary code values D<101101>, D<101100>, and D<101011>, with one bit added as the MSB, in the third to fifth registers Register #3 to #5, respectively. These values may be stored in a manner that replaces the previously stored binary code value D<011111> which represents no change in the output level for the INP2 node.

Finally, the binary code values D<101111>, D<101110>, D<101101>, D<101100>, and D<101011> may be stored in the first to fifth registers Register #1 to #5, respectively.

In step S650, the arithmetic circuit 80 may calculate an average value based on the binary code values stored in the registers and provide the calculated average value as the feedback value D_FINAL to the MUX circuit 40. Through the calculated average value, the input state of the biasing circuit 50 may be determined. For example, if the calculated average value is D<101111>, it may be seen that the voltage of the INN2 node has been formed higher than the voltage of the INP2 by the offset, since the feedback value has been determined to allow more current to flow to the INN2 node in the state where the biasing circuit 50 is connected to the INN2 node (i.e., in the state of the switch elements PNSB=ON and PNS=OFF). In one aspect, the level of the control voltage of the biasing circuit 50 according to the binary code value may be set and adjusted by the user.

In step S660, contrary to step S610, the external voltage (or external signal) supplied to the differential input terminals INP1 and INN1 of the first amplifier 11 may be reconnected. The external voltage applied from the outside may be supplied to the INP and INN nodes, and the connection path between the INP and INN nodes and the differential input terminals of the first amplifier 11 may be established through the switching circuit 20 of the offset calibration circuit. Referring again to FIGS. 4 and 5, at the same time, the switching circuit 20 may disconnect the connection between the reference signal output nodes REF_P and REF_N of the reference signal generation circuit 30 and the differential input terminals of the first amplifier 11 to block the internal voltages of the source driver circuit that were being applied to the INP1 and INN1 nodes.

Additionally, in step S660, the feedback value D_FINAL may be inputted to the biasing circuit 50, and based on this, the biasing circuit 50 may operate to calibrate the offsets of the amplifiers in the receiver circuit.

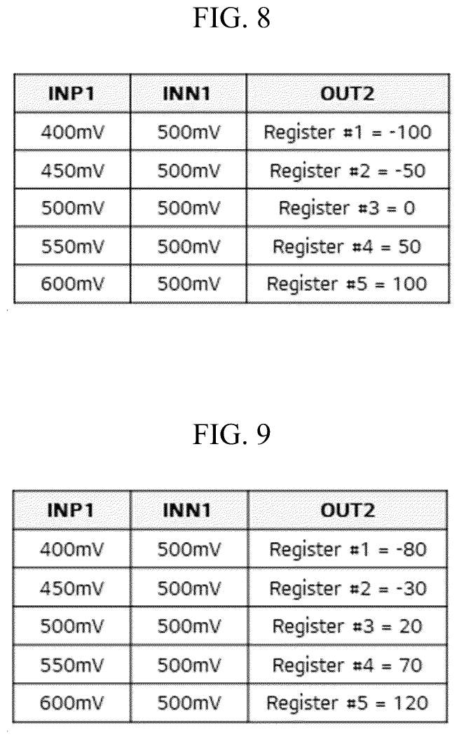

FIGS. 8 and 9 are tables illustrating the offset calibration results according to one aspect of the present disclosure.

Referring to FIG. 8, in an ideal case where there is no offset in the plurality of amplifiers of the receiver circuit, when the voltages shown in the table are inputted to the differential input terminals INP1 and INN1 of the first amplifier 11, values such as OUT2 may be outputted as the output of the second amplifier 12 and stored in the respective registers. It should be noted that the values in FIG. 8 are exemplary values provided to aid understanding of the description.

Referring to FIG. 9, in an actual situation where offsets exist in the plurality of amplifiers of the receiver circuit, when the voltages shown in the table are inputted to the differential input terminals INP1 and INN1 of the first amplifier 11, values such as OUT2 are outputted as the output of the second amplifier 12 and stored in the respective registers. Although the same voltages as in FIG. 8 are inputted, differences occur in the output values due to the offsets of the amplifiers. It should be noted that the values in FIG. 9 are also exemplary values provided to aid understanding of the description.

By applying the offset calibration method of one aspect of the present disclosure to the plurality of amplifiers of the receiver circuit using the offset calibration circuit of one aspect of the present disclosure, the offsets of the amplifiers may be calibrated, thereby changing the output results as shown in FIG. 9 to the outputs as shown in FIG. 8. In an example as shown in FIG. 9, the offsets of the amplifiers may be calibrated based on the average value of 20 from the five registers.

Hereinafter, an offset calibration circuit and an offset calibration method according to another aspect of the present disclosure will be described.

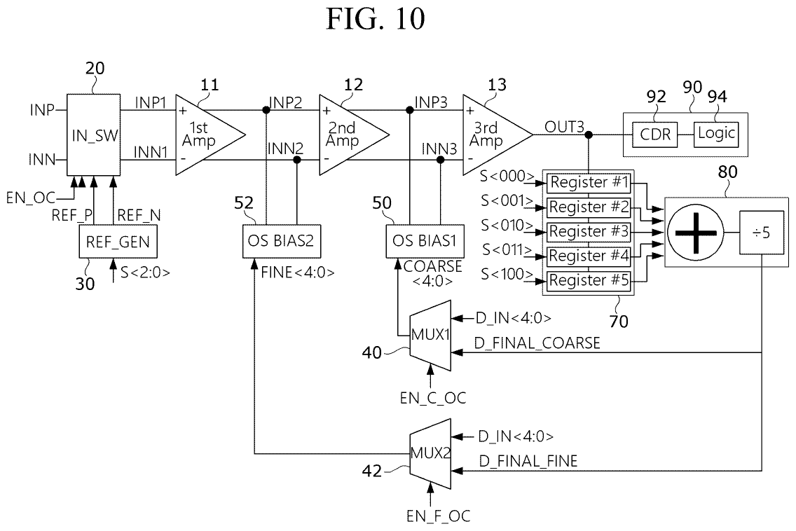

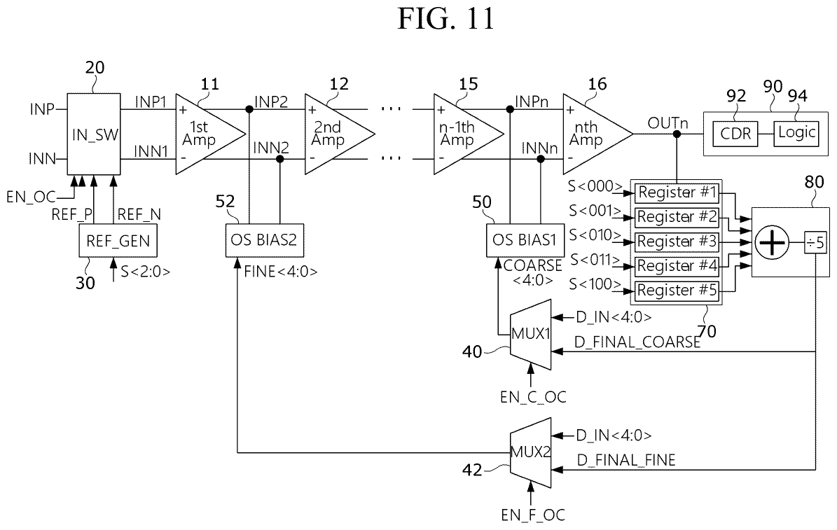

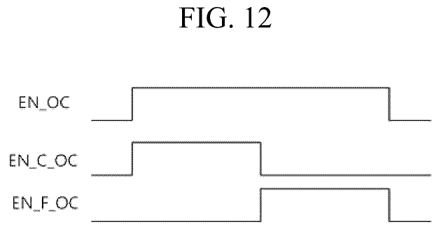

FIG. 10 is a circuit diagram of a source driver circuit according to another aspect of the present disclosure, and FIG. 11 is a circuit diagram of a source driver circuit according to still another aspect of the present disclosure. FIG. 12 is a timing diagram of an offset calibration enable signal according to another aspect of the present disclosure.

Since the basic configuration and operation are similar to those of the source driver circuit shown in FIG. 3, the description will focus on the differences.

Referring to FIG. 10, the receiver circuit may include three amplifiers 11, 12, and 13 connected in a cascade manner, which receives a differential input and differentially outputs to the differential input terminals of a next amplifier. When the receiver circuit receives an external signal and transmits it to the internal circuit, there may be cases where a higher amplification factor of the amplifier is required, and in such cases, three or more amplifiers may be used to achieve a desired amplification factor. When multiple stages of amplifiers are used as described above, the offset may increase further, and it may be difficult to properly calibrate the increased offset using only one biasing circuit 50. Therefore, one more biasing circuit 52 may be added to increase the offset calibration range.

The biasing circuit according to another aspect of the present disclosure may include a first biasing circuit 50 and a second biasing circuit 52, and the MUX circuit may include a first MUX circuit 40 and a second MUX circuit 42.

The first biasing circuit 50 is alternately connected to differential input terminals INP3 and INN3 of a third amplifier 13 and sequentially increases a current flowing through the electrically connected differential input terminals. Binary code values COARSE<4:0> determined by the operation of the first biasing circuit 50 are stored in the plurality of registers 70, and an average value may be calculated by the arithmetic circuit 80 and provided as a feedback value D_FINAL_COARSE to the first MUX circuit 40.

The second biasing circuit 52 is alternately connected to differential output terminals INP2 and INN2 of the first amplifier 11 (or the differential input terminals of the second amplifier 12) and sequentially increases a current flowing through the electrically connected differential input terminals. Binary code values FINE<4:0> determined by the operation of the second biasing circuit 52 are stored in the plurality of registers 70, and an average value may be calculated by the arithmetic circuit 80 and provided as a feedback value D_FINAL_FINE to the second MUX circuit 42.

The plurality of registers 70 may be shared and used during the offset calibration process performed by the first biasing circuit 50 and the offset calibration process performed by the second biasing circuit 52. Since the average value calculated by the operation of the first biasing circuit 50 is stored as the feedback value D_FINAL_COARSE, which is an input of the first MUX circuit 40, and is continuously inputted to the first biasing circuit 50, the binary code values FINE<4:0> generated by the operation of the second biasing circuit 52 may replace the feedback value and be stored in the plurality of registers 70.

The feedback values D_FINAL_COARSE and D_FINAL_FINE initially outputted by the arithmetic circuit 80 may be initial setting values, and in one aspect, the initial setting values of the feedback values D_FINAL_COARSE and D_FINAL_FINE may be set to PNSB=ON, PNS=OFF, and D<00000>. After the offset calibration is performed, the feedback values D_FINAL_COARSE and D_FINAL_FINE are changed to values reflecting the offset calibration.

Referring to FIG. 12, in another aspect of the present disclosure, the operation of the offset calibration circuit may be performed based on the on-off of the offset calibration enable signal EN_OC. More specifically, during the on-level interval of a first offset calibration enable signal EN_C_OC, the offset calibration may be performed by the operation of the first biasing circuit 50, and during the on-level period of a second offset calibration enable signal EN_F_OC, the offset calibration may be performed by the operation of the second biasing circuit 52. Accordingly, the offset calibration circuit according to another aspect of the present disclosure may perform the offset calibration by the operation of the first biasing circuit 50 and then the offset calibration by the operation of the second biasing circuit 52.

Meanwhile, referring to FIG. 11, the receiver circuit may include n amplifiers 11, 12, 15, and 16 (where n is 4 or more) connected in a cascade manner that receives a differential input and differentially outputs to the differential input terminals of a next amplifier.

The biasing circuit according to still another aspect of the present disclosure may include the first biasing circuit 50 and the second biasing circuit 52, and the MUX circuit may include the first MUX circuit 40 and the second MUX circuit 42.

The first biasing circuit 50 is alternately connected to differential input terminals INPn and INNn of an n^{th} amplifier 16 and sequentially increases a current flowing in the electrically connected differential input terminals. The binary code values COARSE<4:0> determined by the operation of the first biasing circuit 50 may be stored in the plurality of registers 70, and an average value may be calculated by the arithmetic circuit 80 and provided as the feedback value D_FINAL_COARSE to the first MUX circuit 40.

The second biasing circuit 52 is alternately connected to the differential output terminals INP2 and INN2 of the first amplifier 11 (or the differential input terminals of the second amplifier 12) and sequentially increases a current flowing through the electrically connected differential input terminals. The binary code values FINE<4:0> determined by the operation of the second biasing circuit 52 may be stored in the plurality of registers 70, and an average value may be calculated by the arithmetic circuit 80 and provided as the feedback value D_FINAL_FINE to the second MUX circuit 42.

Similarly to the aspect of FIG. 10, the plurality of registers 70 may be shared and used during the offset calibration process performed by the first biasing circuit 50 and the offset calibration process performed by the second biasing circuit 52. Additionally, the initial setting values of the feedback values D_FINAL_COARSE, and D_FINAL_FINE initially outputted by the arithmetic circuit 80 may be set to PNSB=ON, PNS-OFF, and D<00000>.

In the aspects as shown in FIGS. 10 and 11 of the present disclosure, in the offset calibration performed by the first biasing circuit 50 at the stage preceding the last amplifier among the plurality of amplifiers connected in a cascade manner, a voltage variation width associated with the biasing of the first biasing circuit 50 may be set higher due to the relatively high amplification factor of the last amplifier. Conversely, in the offset calibration performed by the second biasing circuit 52 at the stage following the first amplifier, a voltage variation width associated with the biasing of the second biasing circuit 52 may be set lower due to the relatively low amplification factor of the first amplifier.

Here, it should be noted that the terms “first amplifier” and “second amplifier” are only named based on the arrangement order of the amplifiers in the circuit diagram as shown in FIG. 10 or FIG. 11, and the technical scope of the present specification is not limited by terms such as “first” or “second.” For example, in one aspect of the present specification, among the plurality of amplifiers, as shown in FIG. 10 or FIG. 11, connected in a cascade manner, which receives a differential input and differentially outputs to the differential input terminals of a next amplifier, the amplifier positioned at the very beginning may be referred to as a “first amplifier,” and the amplifier positioned at the very end may be referred to as a “second amplifier.” What these terms refer to should be interpreted with a specific description.

As described above, the offset calibration circuit according to one aspect of the present specification may achieve more precise offset calibration by intentionally applying, as the input to the amplifier in the receiver circuit, a fixed voltage and variable voltages that have constant voltage differences between adjacent voltages with respect to the fixed voltage, and feeding back to the biasing circuit the average value of the binary code values obtained through the biasing process performed by the biasing circuit to calibrate the offset. Furthermore, the offset calibration circuit may secure a wider adjustable offset range by performing two offset calibration stages using two biasing circuits for the receiver circuit including three or more amplifiers.

Meanwhile, the source driver circuit described above may be provided in the data driving device, and in this case, the data driving device may include the source driver circuit and the display panel having a plurality of pixels that operate by receiving power from the source driver circuit.

Such a source driver circuit may include the receiver circuit that receives an external signal to transmit it to the internal circuit and includes the plurality of amplifiers, and the offset calibration circuit that calibrates the offsets of the plurality of amplifiers in the receiver circuit.

Here, the plurality of amplifiers may include the first amplifier 11 that differentially receives the external signal and differentially outputs it to the next amplifier, and the second amplifier 12 that differentially receives a differential output signal from one of the plurality of amplifiers and outputs it to the internal circuit.

In this case, the offset calibration circuit may include the reference signal generation circuit 30, the biasing circuit 50, and the plurality of registers 70.

The offset calibration circuit generates the fixed voltage and the plurality of variable voltages having a plurality of voltage differences from the fixed voltage by using the reference signal generation circuit 30, and stores a first binary code value of the biasing circuit 50, which causes the output of the second amplifier 12 to transition from a low level to a high level, in one of the plurality of registers.

Additionally, the offset calibration circuit calibrates the offsets of the plurality of amplifiers based on the average value of the first binary code values stored in the plurality of registers for the plurality of variable voltages.

Although the aspects of the present disclosure have been described in more detail with reference to the accompanying drawings, the present disclosure is not necessarily limited to such aspects, and may be variously modified within the scope thereof without departing from the technical spirit of the present disclosure. Therefore, the aspects disclosed in the present disclosure are provided for illustrative purposes only and are not intended to limit the technical concept of the present disclosure, and the scope of the technical concept of the present disclosure is not limited thereto. Therefore, it should be understood that the aspects described above are illustrative in all aspects and do not limit the present disclosure. The scope of protection of the present disclosure should be construed on the basis of the following claims, and all technical concepts within the equivalent scope thereof should be construed as falling within the scope of the present disclosure.

What is claimed is:

1. An offset calibration circuit comprising:
a reference signal generation circuit configured to generate a fixed voltage and a plurality of variable voltages having a plurality of voltage differences from the fixed voltage;
a biasing circuit connected to a plurality of amplifiers and configured to sequentially increase a current flowing through a connected node; and
a plurality of registers in which binary code values of the biasing circuit are stored,
wherein the plurality of amplifiers include a first amplifier configured to differentially receive an external signal and differentially output the signal to a next amplifier, and a second amplifier configured to differentially receive a differential output signal of one of the plurality of amplifiers and output the signal to an internal circuit,
wherein the external signal differentially inputted to the first amplifier is blocked, and the fixed voltage and one of the plurality of variable voltages are inputted to the first amplifier,
a first binary code value of the biasing circuit is stored in one of the plurality of registers, and
offsets of the plurality of amplifiers are calibrated based on an average value of a plurality of the first binary code values stored in the plurality of registers for the respective plurality of variable voltages.

2. The offset calibration circuit of claim 1, wherein voltage values of the plurality of variable voltages include a voltage value of the fixed voltage, and
voltage differences between adjacent voltage values of the plurality of variable voltages are all the same.

3. The offset calibration circuit of claim 1, wherein the reference signal generation circuit generates the plurality of variable voltages by controlling on-off states of an internal switching circuit based on a second binary code value, and
a register in which the first binary code value of the biasing circuit is stored is selected based on the second binary code value.

4. The offset calibration circuit of claim 1, wherein the biasing circuit receives the average value of the first binary code values and supplies an output corresponding to the average value of the first binary code values to the second amplifier to calibrate the offsets of the plurality of amplifiers.

5. The offset calibration circuit of claim 1, wherein the plurality of amplifiers includes at least three amplifiers, and
wherein the biasing circuit includes a first biasing circuit and a second biasing circuit, and
wherein the first biasing circuit is connected to differential input nodes of the second amplifier, and the second biasing circuit is connected to differential output nodes of the first amplifier to calibrate the offsets of the plurality of amplifiers.

6. The offset calibration circuit of claim 5, wherein the offsets of the plurality of amplifiers are calibrated through the first biasing circuit, and subsequently further calibrated through the second biasing circuit.

7. The offset calibration circuit of claim 1, wherein the biasing circuit is alternately connected to differential input nodes of the second amplifier to sequentially increase a current flowing therethrough.

8. A data driving device comprising:
a receiver circuit configured to receive an external signal and transmit it to an internal circuit, the receiver circuit including a plurality of amplifiers; and
an offset calibration circuit configured to calibrate offsets of the plurality of amplifiers of the receiver circuit,
wherein the plurality of amplifiers includes:
a first amplifier configured to differentially receive the external signal and differentially output the signal to a next amplifier; and
a second amplifier configured to differentially receive a differential output signal of one of the plurality of amplifiers and output the signal to the internal circuit, and
wherein the offset calibration circuit includes:
a reference signal generation circuit, a biasing circuit, and a plurality of registers,
wherein the reference signal generation circuit generates a fixed voltage and a plurality of variable voltages having a plurality of voltage differences from the fixed voltage,
the external signal differentially inputted to the first amplifier is blocked, and the fixed voltage and one of the plurality of variable voltages are inputted to the first amplifier,
a first binary code value of the biasing circuit is stored in one of the plurality of registers, and
the offsets of the plurality of amplifiers are calibrated based on an average value of a plurality of the first binary code values stored in the plurality of registers for the respective plurality of variable voltages.

9. The data driving device of claim 8, wherein voltage values of the plurality of variable voltages include a voltage value of the fixed voltage, and
voltage differences between adjacent voltage values of the plurality of variable voltages are all the same.

10. The data driving device of claim 8, wherein the reference signal generation circuit generates the plurality of variable voltages by controlling on-off states of an internal switching circuit based on a second binary code value, and
a register in which the first binary code value of the biasing circuit is stored is selected based on the second binary code value.

11. The data driving device of claim 8, wherein the offset calibration circuit inputs the average value of the first binary code values to the biasing circuit, and
an output of the biasing circuit corresponding to the average value of the first binary code values is supplied to the second amplifier to calibrate the offsets of the plurality of amplifiers.

12. The data driving device of claim 8, wherein the plurality of amplifiers includes at least three amplifiers, and
the biasing circuit includes a first biasing circuit and a second biasing circuit,
wherein the first biasing circuit is connected to differential input nodes of the second amplifier, and the second biasing circuit is connected to differential output nodes of the first amplifier to calibrate the offsets of the plurality of amplifiers.

13. The data driving device of claim 12, wherein the offset calibration circuit calibrates the offsets of the plurality of amplifiers through the first biasing circuit and subsequently further calibrates the offsets of the plurality of amplifiers through the second biasing circuit.

14. The data driving device of claim 8, wherein the biasing circuit is alternately connected to differential input nodes of the second amplifier to sequentially increase a current flowing therethrough.
